(19) United States
(12) Patent Application Publication
(10) Pub. No.: US 2024/0399976 A1
(43) Pub. Date: Dec. 5, 2024

(54) DOCK WITH AIR FLOW ARRANGEMENT FOR HEATING/COOLING AN ELECTRONIC DEVICE AND METHODS OF MAKING AND USING

(71) Applicant: National Products, Inc., Seattle, WA (US)

(72) Inventors: Jeffrey D. Carnevali, Seattle, WA (US); Chad Michael Remmers, Vashon, WA (US)

(21) Appl. No.: 18/205,902

(22) Filed: Jun. 5, 2023

(51) Int. Cl. B60R 11/02; H05K 7/20

(52) U.S. Cl. CPC B60R 11/0241; H05K 7/20145; B60R 2011/0008; B60R 2011/0059; B60R 2011/0071

(57) ABSTRACT

A dock for an electronic device includes a base configured to fit over at least a portion of a back surface of the electronic device; a tray extending from the base for receiving one side of the electronic device, wherein at least one of the base or tray includes an opening through the base or tray; and an air flow arrangement including a hose coupled, or coupleable, to the base or tray for air flow from the hose to pass through the opening in the base or tray and a vent adapter coupled, or coupleable, to the hose and configured for coupling to a vent of an air flow source.

### FIELD

The present invention is directed to a dock for an electronic device with an air flow arrangement for heating/cooling the electronic device. The present invention is also directed to a dock for an electronic device with an air flow arrangement coupleable to an air flow source, such as a vehicle ventilation system.

### BACKGROUND

Electronic devices, such as tablets, mobile phones, personal data assistants, or the like, are sensitive to temperature. When the ambient or device temperature is too hot or cold, an electronic device may shut down, operate slowly, or fail to perform. The ideal operating temperature range of electronic devices often fall outside of the temperature range in environments in which the electronic devices are intended to be used. For example, such electronic devices may be used in ambient or device temperatures that are at or below 0° C. (32° F.) or at or above 37° C. (approximately 100° F.), for example, in a vehicle sitting in the sun. These temperatures are typically outside the recommended operating temperature range of most electronic devices. An electronic device may operate at such temperatures for extended periods of time.

### BRIEF SUMMARY

One embodiment is a dock for an electronic device that includes a base configured to fit over at least a portion of a back surface of the electronic device; a tray extending from the base for receiving one side of the electronic device, wherein at least one of the base or tray includes an opening through the base or tray; and an air flow arrangement including a hose coupled, or coupleable, to the base or tray for air flow from the hose to pass through the opening in the base or tray and a vent adapter coupled, or coupleable, to the hose and configured for coupling to a vent of an air flow source.

In at least some embodiments, the air flow arrangement further includes a hose fitting coupling the hose to the vent adapter. In at least some embodiments, the air flow arrangement further includes a plurality of magnets disposed in the hose fitting or vent adapter or both for magnetically coupling the hose fitting to the vent adapter. In at least some embodiments, the air flow arrangement further includes a plurality of coupling elements made of a magnetic material and disposed in the hose fitting or vent adapter or both for magnetically coupling the hose fitting to the vent adapter.

In at least some embodiments, the vent adapter includes a shape complementary to vents of a specified vehicle or set of vehicles. In at least some embodiments, the air flow arrangement further includes a tie or strap for coupling the vent adapter to the vent of the air flow source. In at least some embodiments, the air flow arrangement further includes a dock connector for coupling the hose to the base or tray of the dock. In at least some embodiments, the opening is in the base. In at least some embodiments, the opening is in the tray.

Another embodiment is a system that includes any of the docks described above and the electronic device. In at least some embodiments, the system further includes a vehicle including a ventilation system configured to be the air flow source.

A further embodiment is a method for cooling or heating an electronic device disposed in a dock. The method includes providing a dock and an air flow arrangement coupled to the dock, wherein the dock includes a base configured to fit over at least a portion of a back surface of the electronic device and a tray extending from the base for receiving one side of the electronic device, wherein at least one of the base or tray includes an opening through the base or tray, wherein the air flow arrangement includes a hose coupled to the base or tray for air flow from the hose to pass through the opening in the base or tray g and a vent adapter coupled to the hose; coupling the vent adapter to a vent of an air flow source; and operating the air flow source to direct cool air or warm air through the hose to the dock to, respectively, cool or heat the electronic device.

In at least some embodiments, the air flow source is a ventilation system of a vehicle. In at least some embodiments, the providing includes coupling the air flow arrangement to the dock. In at least some embodiments, the coupling includes attaching the vent adapter to the vent using at least one tie or strap. In at least some embodiments, the method further includes decoupling the hose from the vent adapter.

In at least some embodiments, the air flow arrangement further includes a hose fitting coupled to the hose and the method further includes coupling the hose to the vent adapter using the hose fitting. In at least some embodiments, the air flow arrangement further includes a plurality of magnets disposed in the hose fitting or vent adapter or both, wherein coupling the hose to the vent adapter using the hose fitting includes magnetically coupling the hose fitting to the vent adapter using the magnets. In at least some embodiments, the air flow arrangement further includes a plurality of coupling elements made of a magnetic material and disposed in the hose fitting or vent adapter or both, wherein the magnetically coupling includes magnetically coupling the hose fitting to the vent adapter using the magnets and the coupling elements.

Yet another embodiment is an air flow arrangement that includes a hose; a dock connecter coupled, or coupleable, to the hose and configured for coupling to a dock for an electronic device; a hose fitting coupled to the hose; a vent adapter configured for coupling to a vent of an air flow source; and a plurality of magnets disposed in the hose fitting or vent adapter or both and arranged for removably coupling the vent adapter to the hose fitting.

### BRIEF DESCRIPTION OF THE DRAWINGS

Non-limiting and non-exhaustive embodiments of the present invention are described with reference to the following drawings. In the drawings, like reference numerals refer to like parts throughout the various figures unless otherwise specified.

For a better understanding of the present invention, reference will be made to the following Detailed Description, which is to be read in association with the accompanying drawings, wherein:

FIG. 1A is a schematic perspective front view of another embodiment of a dock with an electronic device disposed in the dock and an air flow arrangement attached to a base of the dock, according to the invention;

FIG. 1B is a schematic perspective front view of the dock with air flow arrangement of FIG. 1A with the electronic device removed, according to the invention;

FIG. 1C is a schematic perspective back view of the dock with air flow arrangement of FIG. 1A with the electronic device removed, according to the invention;

FIG. 1D is a schematic perspective back view of the dock with air flow arrangement of FIG. 1A with a mount attached to the dock, according to the invention;

FIG. 2 is a schematic perspective front view of another embodiment of a dock with an electronic device disposed in the dock and an air flow arrangement attached to a tray of the dock, according to the invention;

FIG. 3A is a schematic perspective back view of a vent adapter of an air flow arrangement attached to a vent cap of an air flow source, according to the invention;

FIG. 3B is a schematic perspective front view of the vent adapter and vent cap of FIG. 3A, according to the invention;

FIG. 3C is a schematic perspective view of the vent adapter and vent cap of FIG. 3A separated from each other, according to the invention; and

FIG. 3D is a schematic perspective side view, with partial cut-away section, of the vent adapter and vent cap of FIG. 3A including a hose fitting of the air flow arrangement, according to the invention.

### DETAILED DESCRIPTION

The present invention is directed to a dock for an electronic device with an air flow arrangement for heating/cooling the electronic device. The present invention is also directed to a dock for an electronic device with an air flow arrangement coupleable to an air flow source, such as a vehicle ventilation system.

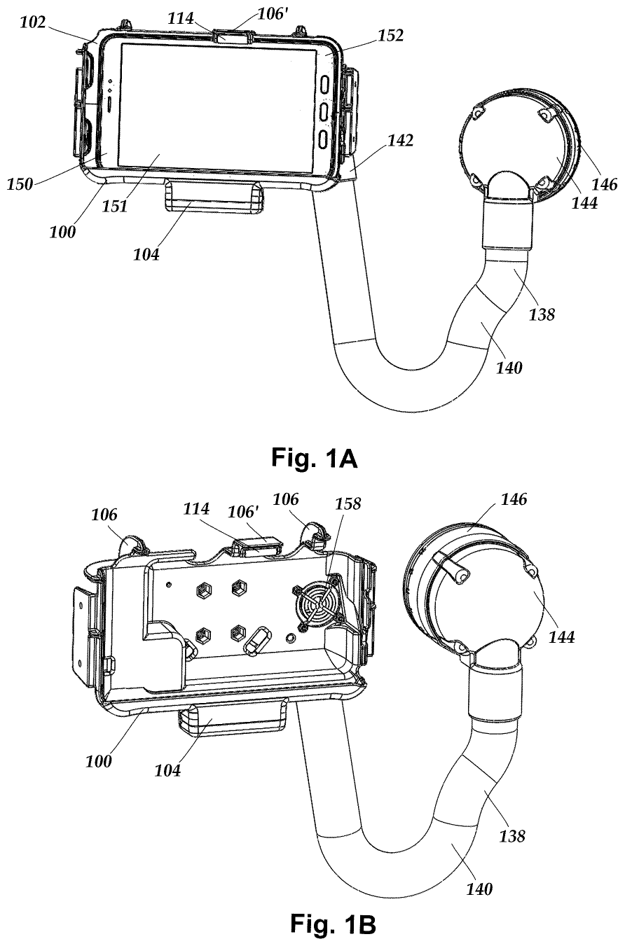

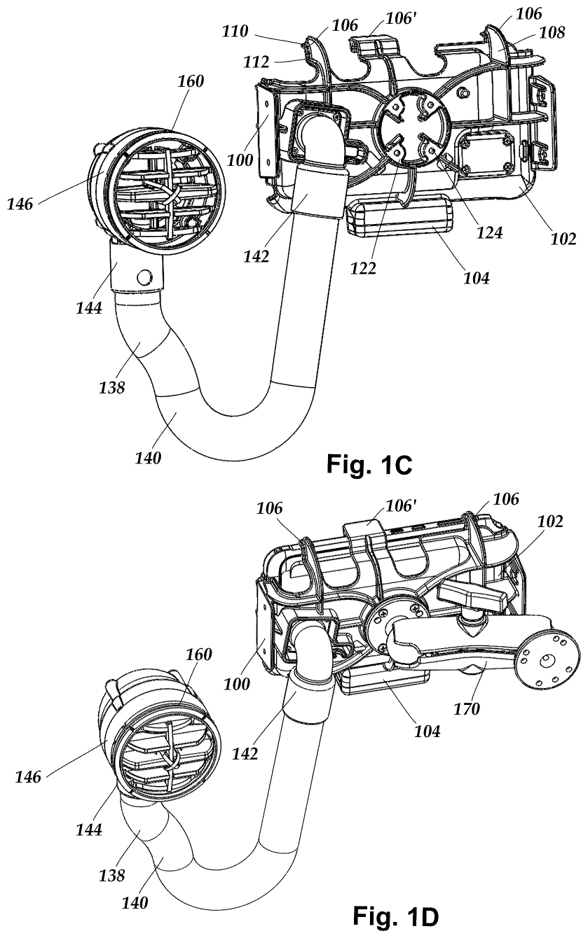

To heat or cool an electronic device, a dock can include an air flow arrangement. As illustrated in FIGS. 1A to 1D, one embodiment of a dock 100 includes a base 102 and a tray 104 extending from a base 102. The tray 104 receives one side of an electronic device 150, such as a mobile device (for example, a mobile phone, tablet, personal data assistant, or the like) or a laptop. Examples of docks that can be modified to include an air flow arrangement can be found in, for example, U.S. Pat. Nos. 7,573,706; 7,894,180; 8,179,672; 9,036,343; 9,831,904; 11,029,731; 11,076,032; 11,277,506; 11,489,350; and 11,652,326 and U.S. Patent Application Publications Nos. 2022/0253097 and 2023/0045485, all of which are incorporated by reference in their entireties.

In at least some embodiments, an electronic device 150, such as a mobile device, may be disposed within a cover 152. In at least some embodiments, the dock 102 includes one or more contacts 126 disposed in the tray 104 and configured to couple to contacts on the cover 152 or electronic device 150. Examples of covers 152 for an electronic device 150 are described in U.S. Pat. Nos. 9,195,279; 9,331,444; 9,529,387; 9,602,639; 9,632,535; 9,706,026; 10,389,399; 10,050,658; 10,054,984; 10,454,515; 10,630,334; 10,666,309; 10,778,275 10,812,643; 11,029,731; 11,076,032; 11,165,458; 11, 277,506; and 11,289,864 and U.S. Patent Applications Publication Nos. 2021/0391678 and 2021/0392773, all of which are incorporated herein by reference in their entireties.

In at least some embodiments, the dock 100 also includes at least one attachment arm 106, 106′ extending from the base 102 for attaching the dock to the electronic device 150. Each attachment arm 106, 106′ has a back engagement portion 108, a front engagement portion 110, and a width portion 112 extending between the back and front engagement portions. In at least some embodiments, the back and front engagement portions 108, 110 are arranged to fit snugly on the electronic device 150 disposed therein to retain the electronic device in the dock 100. In at least some embodiments, the front engagement portion 110 of an attachment arm 106′ includes a roller 114 which can roll on an axle held by two legs to facilitate retention of the electronic device 150 within the dock 100.

In at least some embodiments, the dock 100 can have attached, or attachable, to one or more accessories, such as a mount 170. The mount 170 can be attached to a mounting arrangement 122 on the dock 100 which includes multiple attachment apertures 124 for receiving a fastener to attach the mount to the mounting arrangement. Non-limiting examples of mounts and mounting devices can be found at, for example, U.S. Pat. Nos. 5,845,885; 6,561,476; 7,320,50; 7,997,554; 8,454,178; 8,505,861; 9,831,904; RE42,060; RE42,581; and RE43,806, all of which are incorporated herein by reference in their entireties.

As indicated above, electronic devices, such as tablets, phones, or personal data assistants, are sensitive to temperature. As described herein, a dock can include an air flow arrangement for directing heating or cooling air from an external source, such as a vehicle's ventilation system (e.g., a heating or cooling system) to heat or cool the electronic device. FIGS. 1A to 1D illustrate one embodiment of such an air flow arrangement 138 attached (or attachable) to the dock 100. The air flow arrangement 138 includes a hose 140, a dock connector 142 for attaching the hose to the dock 100 over an opening 130 in the dock, a hose fitting 144, and a vent adapter 146 that is coupled to the hose by the hose fitting and is configured for coupling to a vent of an air flow source. The components of the air flow arrangement 138 can be made of any suitable materials including, but not limited to, plastic, metal, or the like or any combination thereof.

In at least some embodiments, the hose 140 and one or both of the dock connector 142 and the hose fitting 144 can be a single, unitary, non-divisible piece. In at least some embodiments, the hose fitting 144 and vent adapter 146 can be a single, unitary, non-divisible piece. The term “non-divisible” means that two or more components are not intended to be separated under normal use or circumstances.

The dock 100 includes a hose connection port 154 disposed around an opening 156 for passage of heating or cooling air from the air flow arrangement 138 through the base 102 or tray 104 to the electronic device 150 disposed in the dock 100. In at least some embodiments, a grill 158 (or filter) can be placed over the opening 156. In at least some embodiments, the dock connector 142 and hose connection port 154 can be permanently attached or removably attached to each other.

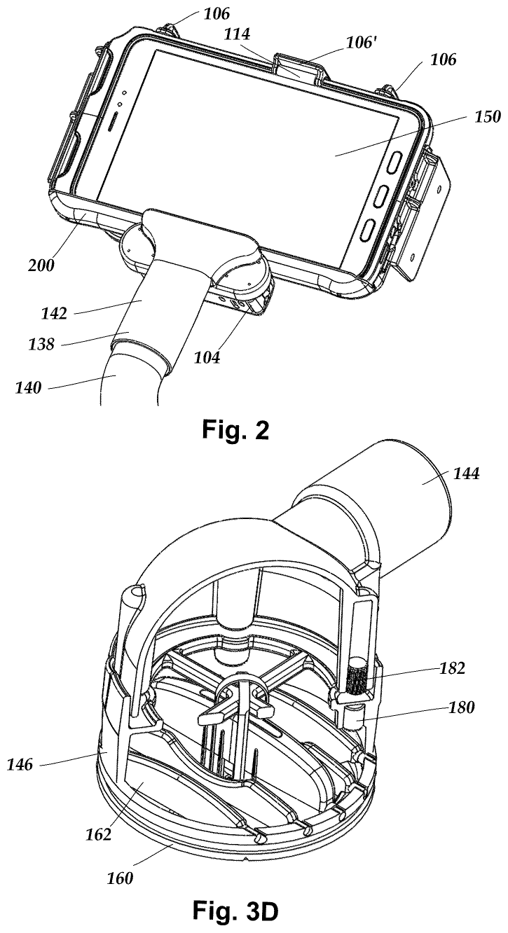

In the embodiment of the dock 100 illustrated in FIGS. 1A to 1D, the hose connector port 154 is part of the base 102 and the opening extends through the base. In another embodiment of a dock 400, illustrated in FIG. 2, the hose connector port 154 is part of the tray 104 and the opening 156 extends through the tray. In at least some embodiments, the dock 400 and air flow arrangement 138 illustrated in FIG. 4 can flow cool or warm air over the screen or display 151 of the electronic device 150. When contacts of the dock 400 and electronic device 150 are positioned on or near the tray, the air flow arrangement 138 and dock 400 can be used to cool or heat these contacts.

In at least some embodiments, the air flow arrangement 138 is arranged for coupling to a vehicle's heating/cooling vents or other ventilation system. In at least some embodiments, the vent adapter 146 has a shape that is complementary to the ventilation vents of a particular vehicle or set of vehicles. In at least some embodiments, a user can control the temperature of the electronic device 150 using the temperature controls of the vehicle.

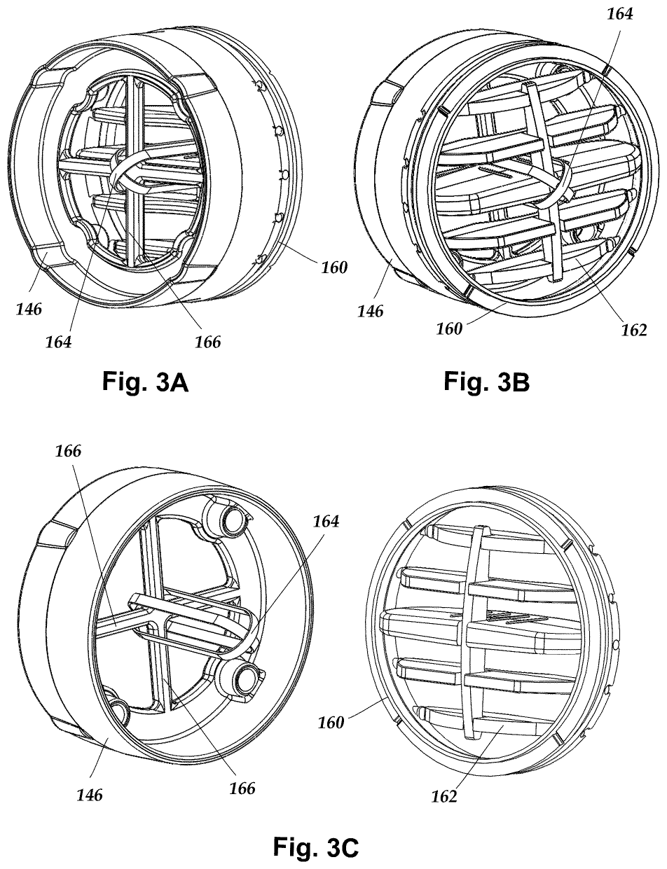

FIGS. 3A to 3C illustrate coupling or attachment of the vent adapter 146 to a vent cap 160 of a ventilation system. In at least some embodiments, the vent cap 160 includes fins 162 which may or may not be adjustable. Preferably, the vent adapter 146 is removably attached to the vent cap 160. In at least some embodiments, the air flow arrangement 138 includes one or more ties or straps 164 (or any other suitable fastener) for attaching the vent adapter 146 to the vent cap 160. In at least some embodiments, the vent adapter 146 includes one or more crossbars 166 (or any other suitable structure) for attaching the tie(s) or strap(s) 164. In at least some embodiments, the tie or strap 164 is a nylon tie.

In other embodiments, the hose fitting 144 and vent adapter 146 are two separate pieces that are removably coupled or attached to each other. The hose fitting 144 and vent adapter 146 can be removably coupled or attached using any suitable attachment mechanism including, but not limited to, snap-fit arrangements, buckles or other fasteners, rotating connectors (for example, screw type or pin/track type rotating connectors), or the like or any combination thereof.

FIG. 3D illustrated another attachment mechanism in which magnets 180 are disposed in at least one of the hose fitting 144 or the vent adapter 146. In at least some embodiments, magnets 180 can be provided in both the hose fitting 144 and the vent adapter 146 and arranged to couple to each other. In other embodiments, coupling elements, such as plugs 182, made of a magnetic material, such as iron or steel, can be disposed in at least one of the hose fitting 144 or the vent adapter 146 and arranged to couple to opposing magnets in the hose fitting or the vent adapter.

In some embodiments, the magnets 180 are disposed in either the hose fitting 144 or the vent adapter 146 and the plugs 182 are disposed in the other one of the hose fitting or the vent adapter. In the embodiment illustrated in FIG. 3D, the magnets 180 are disposed in the vent adapter 146 and the plugs 182 in the hose fitting 144. In other embodiments, alternating (or other arrangements of) magnets 180 and plugs 182 can be provided in each of the hose fitting 144 and vent adapter 146.

In at least some embodiments, the magnets 180 and plugs 182 (or magnets alone) can provide for an arrangement with quick attachment or detachment of the vent adapter 146 and the hose fitting 144. In at least some embodiments, the vent adapter 146 securely attached to the vent cap 160 of an air flow source, such as a vehicle ventilation system. Then, the hose fitting 144 can be quickly attached or detached from the air flow source using the arrangement of magnets 180/plugs 182. For example, when the electronic device 150 and dock 100 is removed from the vehicle, this quick attachment/detachment arrangement allow for faster and convenient removal.

The above specification provides a description of the manufacture and use of the invention. Since many embodiments of the invention can be made without departing from the spirit and scope of the invention, the invention also resides in the claims hereinafter appended.

What is claimed as new and desired to be protected by Letters Patent of the United States is:

1. A dock for an electronic device, the dock comprising:
a base configured to fit over at least a portion of a back surface of the electronic device;
a tray extending from the base for receiving one side of the electronic device, wherein at least one of the base or tray comprises an opening through the base or tray; and
an air flow arrangement comprising
a hose coupled, or coupleable, to the base or tray for air flow from the hose to pass through the opening in the base or tray, and
a vent adapter coupled, or coupleable, to the hose and configured for coupling to a vent of an air flow source.

2. The dock of claim 1, wherein the air flow arrangement further comprises a hose fitting coupling the hose to the vent adapter.

3. The dock of claim 2, wherein the air flow arrangement further comprises a plurality of magnets disposed in the hose fitting or vent adapter or both for magnetically coupling the hose fitting to the vent adapter.

4. The dock of claim 3, wherein the air flow arrangement further comprises a plurality of coupling elements made of a magnetic material and disposed in the hose fitting or vent adapter or both for magnetically coupling the hose fitting to the vent adapter.

5. The dock of claim 1, wherein the vent adapter comprises a shape complementary to vents of a specified vehicle or set of vehicles.

6. The dock of claim 1, wherein the air flow arrangement further comprises a tie or strap for coupling the vent adapter to the vent of the air flow source.

7. The dock of claim 1, wherein the air flow arrangement further comprises a dock connector for coupling the hose to the base or tray of the dock.

8. The dock of claim 1, wherein the opening is in the base.

9. The dock of claim 1, wherein the opening is in the tray.

10. A system comprising:
the dock of claim 1; and
the electronic device.

11. The system of claim 10, further comprising a vehicle comprising a ventilation system configured to be the air flow source.

12. A method for cooling or heating an electronic device disposed in a dock, the method comprising:
providing a dock and an air flow arrangement coupled to the dock, wherein the dock comprises a base configured to fit over at least a portion of a back surface of the electronic device and a tray extending from the base for receiving one side of the electronic device, wherein at least one of the base or tray comprises an opening through the base or tray, wherein the air flow arrangement comprises a hose coupled to the base or tray for air flow from the hose to pass through the opening in the base or tray and a vent adapter coupled to the hose;
coupling the vent adapter to a vent of an air flow source; and
operating the air flow source to direct cool air or warm air through the hose to the dock to, respectively, cool or heat the electronic device.

13. The method of claim 12, wherein the air flow source is a ventilation system of a vehicle.

14. The method of claim 12, wherein the air flow arrangement further comprises a hose fitting coupled to the hose, the method further comprising coupling the hose to the vent adapter using the hose fitting.

15. The method of claim 14, wherein the air flow arrangement further comprises a plurality of magnets disposed in the hose fitting or vent adapter or both, wherein coupling the hose to the vent adapter using the hose fitting comprises magnetically coupling the hose fitting to the vent adapter using the magnets.

16. The method of claim 15, wherein the air flow arrangement further comprises a plurality of coupling elements made of a magnetic material and disposed in the hose fitting or vent adapter or both, wherein the magnetically coupling comprises magnetically coupling the hose fitting to the vent adapter using the magnets and the coupling elements.

17. The method of claim 12, wherein the providing comprises coupling the air flow arrangement to the dock.

18. The method of claim 12, wherein the coupling comprises attaching the vent adapter to the vent using at least one tie or strap.

19. The method of claim 12, further comprising decoupling the hose from the vent adapter.

20. An air flow arrangement comprising
a hose;
a dock connecter coupled, or coupleable, to the hose and configured for coupling to a dock for an electronic device;
a hose fitting coupled to the hose;
a vent adapter configured for coupling to a vent of an air flow source; and
a plurality of magnets disposed in the hose fitting or vent adapter or both and arranged for removably coupling the vent adapter to the hose fitting.
